(19) United States
(12) Patent Application Publication
(10) Pub. No.: US 2024/0321747 A1
(43) Pub. Date: Sep. 26, 2024

(54) BACKSIDE POWER ISLANDS FOR BACKSIDE POWER APPLICATIONS

(71) Applicant: International Business Machines Corporation, Armonk, NY (US)

(72) Inventors: Ruilong Xie, Niskayuna, NY (US); Christopher J. Penny, Saratoga Springs, NY (US); Kisik Choi, Watervliet, NY (US); Koichi Motoyama, Clifton Park, NY (US); Nicholas Anthony Lanzillo, Wynantskill, NY (US); Chih-Chao Yang, Glenmont, NY (US)

(21) Appl. No.: 18/123,613

(22) Filed: Mar. 20, 2023

(51) Int. Cl. H01L 23/528; H01L 21/78; H01L 21/8238; H01L 27/092; H01L 29/06; H01L 29/417; H01L 29/423; H01L 29/66; H01L 29/775

(52) U.S. Cl. CPC H01L 23/5286; H01L 21/7806; H01L 21/823807; H01L 21/823871; H01L 27/092; H01L 29/0673; H01L 29/41733; H01L 29/42392; H01L 29/66439; H01L 29/775

(57) ABSTRACT

A semiconductor structure is provided that includes a plurality of backside power islands, rather than backside power rails. The backside power islands are present in a first device track and a second device track. Each backside power island located in the first device track and the second device track are isolated by a first cut region, and the backside power islands that are located in the first device track are separated from the backside power islands located in the second device track by a second cut region. The second cut region is oriented perpendicular to the first cut region.

### BACKGROUND

The present application relates to semiconductor technology, and more particularly to a semiconductor structure containing a plurality of backside power islands.

When forming a structure including a plurality of complementary metal oxide semiconductor (CMOS) devices, such as integrated circuits, standard cells can be used as a base unit for designing and manufacturing the integrated circuits. The standard cell(s) can be used to form one or more functional circuits, and each standard cell can have the same footprint. Using standard cells when designing complex circuits and components reduces design and manufacture costs.

In use, each standard cell of a semiconductor structure requires power input (Vdd) and ground (Vss) connections. To power the various components thereof, each standard cell is generally coupled to a backside power rail which is electrically connected to an active layer of the standard cell to provide the power (Vdd). In some instances, a plurality of backside power rails may be provided for each standard cell to respectively provide the power (Vdd) and the ground (Vss).

In cells containing backside contact structures that provide direct connection of the backside power rails to one of the source/drain regions of a transistor, the backside first metal level (M1) side-by-side space is very small. Even with this very small side-by-side space, the backside overlay requirement is very high (i.e., sigma is less than 10 nm). This problem becomes even worse for mixed cell heights (i.e., 6T cells and 9T cells).

### SUMMARY

A semiconductor structure is provided that includes a plurality of backside power islands, rather than backside power rails. In one embodiment, the semiconductor structure includes backside power islands located in both a first device track and a second device track, wherein each backside power island located in the first device track and the second device track is isolated by a first cut region, and the backside power islands located in the first device track are separated from the backside power islands located in the second device track by a second cut region, and further wherein the second cut region is oriented perpendicular to the first cut region. The inclusion of backside power islands, rather than backside power rails, allows for a structure having mixed cell heights and a small side-by-side space backside first metal level.

In some embodiments of the present application, each of the first device track and the second device track includes p-type field effect transistors and n-type field effect transistors arranged in rows and columns.

In some embodiments of the present application, the first cut region is located between each n-type field effect transistor to p-type field effect transistor pair present in the first device track and the second device track.

In some embodiments of the present application, the backside power islands in the first device track have a first width and the backside power islands in the second device track have a second width, wherein the first width is less than the second width.

In some embodiments of the present application, the first device track includes first active areas each of which has a first width and the second device track includes second active areas each of which has a second width that is greater than the first width.

In some embodiments of the present application, the first cut region and the second cut region are both filled with a backside interconnect dielectric material layer.

In some embodiments of the present application, the backside interconnect dielectric material layer in both the first cut region and the second cut region is in direct physical contact with a sidewall of at least one of the backside power islands.

In some embodiments of the present application, the backside interconnect dielectric material layer contacts a surface of a backside power distribution network.

In some embodiments of the present application, the backside power distribution network is connected to at least one of the backside power islands that are located in both the first device track and second device track by a metal via contact structure.

In some embodiments of the present application, the metal via contact structure includes a diffusion barrier liner located along a sidewall and a bottom wall of an electrically conductive metal or electrically conductive metal alloy.

In some embodiments of the present application, a first surface of each of the backside power islands contacts a diffusion barrier layer, and a second surface of each of the backside power islands opposite the first surface contacts a hard mask layer, and wherein the first surface of each of the backside power islands is located further from the backside power distribution network than the second surface of each of the backside power islands.

In some embodiments of the present application, at least one of the backside power islands is electrically connected to a source/drain region of a p-type field effect transistor or an n-type field effect transistor in at least one of the first device track or the second device track by a backside source/drain contact structure.

In some embodiments of the present application, at least one source/drain region of either a p-type field effect transistor or an n-type field effect transistor in at least one of the first device track or the second device track is electrically connected to a frontside back-end-of-the-line (BEOL) structure by a frontside source/drain contact structure.

In some embodiments of the present application, the structure further includes a carrier wafer located on a surface of the frontside BEOL structure.

In some embodiments of the present application, the source/drain region that is electrically connected to the frontside BEOL structure is located on a surface of a bottom dielectric isolation layer.

In some embodiments of the present application, the p-type field effect transistors and the n-type field effect transistors are nanosheet containing transistors including a gate structure wrapped around at least one semiconductor channel material nanosheet.

In some embodiments of the present application, a diffusion break point structure separates the first device track from the second device track, and in such embodiments, the second cut region is located beneath the diffusion break point structure.

In some embodiments of the present application, the diffusion break point structure is composed of a dielectric material, and the diffusion break point structure extends into a backside interlayer dielectric material layer.

In some embodiments of the present application, the backside interlayer dielectric material layer is located above each of the backside power islands.

In another embodiment of the present application, the semiconductor structure includes a first device track located laterally adjacent to a second device track, wherein each of the first device track and the second device track includes p-type field effect transistors and n-type field effect transistors arranged in rows and columns; a diffusion break point structure separating the first device track from the second device track; and backside power islands located in both the first device track and the second device track, wherein the backside power islands that are located in the first device track and the backside power islands that are located in the second device track are isolated by a first cut region, and the backside power islands located in the first device track are separated from the backside power islands located in the second device track by a second cut region, and further wherein the second cut region is located beneath the diffusion break point structure and is oriented perpendicular to the first cut region.

In this another embodiment of the present application, the first cut region can be located between each n-type field effect transistor to p-type field effect transistor pair present in the first device track and the second device track.

In this another embodiment of the present application, the backside power islands in the first device track have a first width and the backside power islands in the second device track have a second width, wherein the first width is less than the second width.

In this another embodiment of the present application, the first device track includes first active areas each of which has a first width and the second device track includes second active areas each of which has a second width that is greater than the first width.

In this another embodiment of the present application, the first cut region and the second cut region are both filled with a backside interconnect dielectric material layer.

In this another embodiment of the present application, the backside interconnect dielectric material layer in both the first cut region and the second cut region is in direct physical contact with a sidewall of at least one of the backside power islands.

### BRIEF DESCRIPTION OF THE DRAWINGS

FIG. 1 is a top down view showing a device layout that can be employed in the present application, the device layout including a plurality of gate structures located in different device tracks; the illustrated device layout includes cut Y1-Y1, cut Y2-Y2, and cut X-X.

FIGS. 2A, 2B and 2C are cross sectional views through cuts Y1-Y1, Y2-Y2 and X-X respectively, of an exemplary semiconductor structure that can be employed in the present application, the exemplary structure includes a substrate, a placeholder material layer located on the substrate, and a material stack of alternating layers of sacrificial semiconductor material and semiconductor channel material located on the placeholder material layer.

FIGS. 3A, 3B and 3C are cross sectional views of the exemplary semiconductor structure shown in FIGS. 2A, 2B and 2C, respectively, after patterning the material stack and the placeholder material layer into individual patterned material stacks, each individual patterned material stack includes a remaining portion of the material stack and a remaining portion of the placeholder material layer.

FIG. 4 is a top down view showing the device layout shown in FIG. 1 showing the areas in which backside contacts (BC) will be subsequently formed.

FIGS. 5A, 5B and 5C are cross sectional views of the exemplary semiconductor structure shown in FIGS. 3A, 3B and 3C, respectively, after nanosheet device processing including formation of sacrificial gate structures, gate spacers, a bottom dielectric isolation layer, nanosheet stacks, a backside contact placeholder material and source/drain regions, each nanosheet stack including alternating sacrificial semiconductor material nanosheets and semiconductor channel material nanosheets.

FIGS. 6A, 6B and 6C are cross sectional views of the exemplary semiconductor structure shown in FIGS. 5A, 5B and 5C, respectively, after forming a frontside interlayer dielectric (ILD) material layer and planarization.

FIGS. 7A, 7B and 7C are cross sectional views of the exemplary semiconductor structure shown in FIGS. 6A, 6B and 6C, respectively, after forming a self-aligned diffusion break point area.

FIGS. 8A, 8B and 8C are cross sectional views of the exemplary semiconductor structure shown in FIGS. 7A, 7B and 7C, respectively, after forming a dielectric material in the self-aligned diffusion break point area to provide a diffusion break point structure.

FIGS. 9A, 9B and 9C are cross sectional views of the exemplary semiconductor structure shown in FIGS. 8A, 8B and 8C, respectively, after further nanosheet device processing including removing the sacrificial gate structures, suspending the semiconductor channel material nanosheets of each nanosheet stack, forming a gate structure wrapping around the suspended semiconductor channel material nanosheets of each nanosheet stack, forming an additional frontside ILD material, frontside source/drain contact structures, a frontside back-end-of-the-line (BEOL) structure and a carrier wafer.

FIGS. 10A, 10B and 10C are cross sectional views of the exemplary semiconductor structure shown in FIGS. 9A, 9B and 9C, respectively, after removing a first semiconductor material layer of the substrate.

FIGS. 11A, 11B and 11C are cross sectional views of the exemplary semiconductor structure shown in FIGS. 10A, 10B and 10C, respectively, after removing an etch stop layer and a second semiconductor layer of the substrate.

FIGS. 12A, 12B and 12C are cross sectional views of the exemplary semiconductor structure shown in FIGS. 11A, 11B and 11C, respectively, after forming a first backside ILD material layer.

FIGS. 13A, 13B and 13C are cross sectional views of the exemplary semiconductor structure shown in FIGS. 12A, 12B and 12C, respectively, after removing the backside contact placeholder material to physically expose a surface of some of the source/drain regions and forming backside source/drain contact structures contacting the physically exposed surfaces of the source/drain regions.

FIGS. 14A, 14B and 14C are cross sectional views of the exemplary semiconductor structure shown in FIGS. 13A, 13B and 13C, respectively, after forming a diffusion barrier layer, and a backside power rail electrically conductive material layer.

FIGS. 15A, 15B and 15C are cross sectional views of the exemplary semiconductor structure shown in FIGS. 14A, 14B and 14C, respectively, after forming a hard mask layer on the backside power rail electrically conductive material layer, and performing a first backside metal cut (i.e., a X direction cut) into the hard mask layer.

FIGS. 16A, 16B and 16C are cross sectional views of the exemplary semiconductor structure shown in FIGS. 15A, 15B and 15C, respectively, after forming an organic planarization layer, and performing a second backside metal cut (i.e., a Y direction cut) into the organic planarization layer and the hard mask layer.

FIGS. 17A, 17B and 17C are cross sectional views of the exemplary semiconductor structure shown in FIGS. 16A, 16B and 16C, respectively, after removing the organic planarization layer, and patterning the backside power rail electrically conductive material layer utilizing the patterned hard mask layer as an etch mask.

FIGS. 18A, 18B and 18C are cross sectional views of the exemplary semiconductor structure shown in FIGS. 17A, 17B and 17C, respectively, after forming a second backside ILD material layer.

FIGS. 19A, 19B and 19C are cross sectional views of the exemplary semiconductor structure shown in FIGS. 18A, 18B and 18C, respectively, after forming metal via contact structures and a backside power distribution network.

FIG. 20 is a schematic drawing showing prior art backside power rails.

FIG. 21 is a schematic drawing showing backside power islands in accordance with the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

As mentioned above, a semiconductor structure is provided that includes a plurality of backside power islands, rather than backside power rails. In the present application, backside power islands are cut segments of a backside power rail electrically conductive material layer. The backside power islands are present in a first device track (i.e., first device region) and a second device track (i.e., second device region). The backside power islands that are located in the first device track and the backside power islands that are located in the second device track are isolated by a first cut region; the first cut region is typically located between each n-type field effect transistor to p-type field effect transistor pair that is present in the first device track and the second device track. The backside power islands that are located in the first device track are separated from the backside power islands located in the second device track by a second cut region. In the present application, the second cut region is oriented perpendicular to the first cut region. The second cut region is located beneath a diffusion break point structure (i.e., dielectric material pillar) that separates the first device track from the second device track. The second cut region runs along an entire length of the diffusion break point structure. The inclusion of backside power islands, rather than backside power rails, allows for a structure having mixed cell heights and a small side-by-side space backside first metal level.

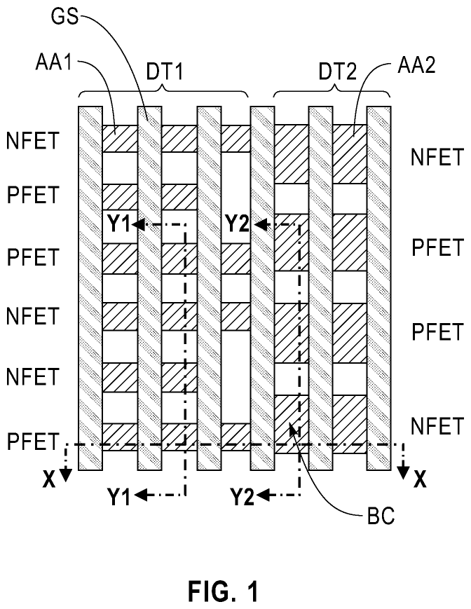

Referring first to FIG. 1, there is illustrated a device layout that can be employed in the present application. The illustrated device layout of FIG. 1 includes a plurality of gate structures, GS, located in different device tracks (i.e., a first device track DT1 and a second device track DT2). In the present application, DT1 has a first active area (AA1), and DT2 has a second active area (AA2), wherein AA2 has a width that is greater (i.e., wider) than AA1. The different device tracks, i.e., DT1 and DT2, are located laterally adjacent to each other and each includes p-type field effect transistors (i.e., PFETs) and n-type field effect transistors (NFETs) arranged in rows and columns. The NFETs and PFETs are typically, but not necessarily always, nanosheet transistors that include a gate structure wrapped around at least one semiconductor channel material nanosheet (preferably the gate structure wraps around a plurality of vertical stacks and spaced apart semiconductor channel material nanosheets). In some embodiments and as shown in FIG. 1, DT1 is a 6T design that includes, reading from the bottom of the page upwards, a column of PFET, NFET, NFET, PFET, PFET and NFET, while DT2 is a 9T design that includes, reading from the bottom of the page upwards, a column of NFET, PFET, PFET and NFET. In the present application, the X-X cut is along a row containing the bottommost PFET in DT1 and the bottommost NFET in DT2, the Y1-Y1 cut is located between the gate structures, GS, located in DT1 and along the lengthwise direction of the gate structures, GS, and the Y2-Y2 cut is located between the gate structures, GS, located in DT2 and along the lengthwise direction of the gate structures, GS. It is noted that the device layout is not limited to one including 6T and 9T devices.

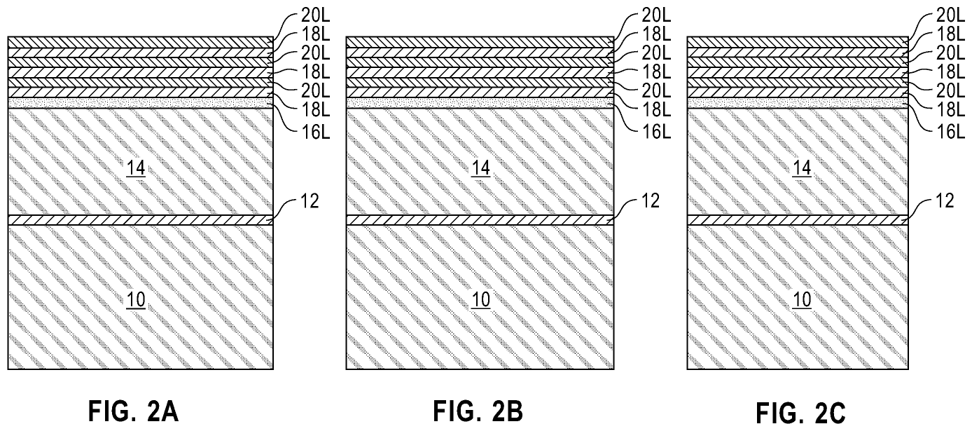

Referring now FIGS. 2A, 2B and 2C, there are illustrated an exemplary structure through cuts Y1-Y1, Y2-Y2 and X-X of FIG. 1 respectively, that can be employed in the present application. The exemplary structure includes a substrate 10, 12 and 14, a placeholder material layer 16L located on the substrate 10, 12 and 14, and a material stack of alternating layers of sacrificial semiconductor material (i.e., sacrificial semiconductor material layers 18L) and semiconductor channel material (i.e., semiconductor channel material layers 20L) located on the placeholder material layer 16L.

In some embodiments, and as illustrated in FIGS. 2A, 2B and 2C, the substrate can include a first semiconductor material layer 10, an etch stop layer 12 and a second semiconductor material layer 14. In other embodiments, the etch stop layer 12 and the second semiconductor material layer 14 can be omitted and in such embodiments, the substrate is composed of the first semiconductor material layer 10. In yet other embodiments, the etch stop layer 12 can be omitted and in such embodiments, the substrate is composed of the first semiconductor material layer 10 and the second semiconductor material layer 14 (in such embodiments the semiconductor material that provides the first and second semiconductor material layers 10, 14 are compositionally different from each other).

The first semiconductor material layer 10 is composed of a first semiconductor material. The second semiconductor material layer 14 is composed of a second semiconductor material. The term “semiconductor material” is used throughout the present application to denote a material having semiconducting properties. Examples of semiconductor materials that can be used in the present application in providing the first semiconductor material and the second semiconductor material include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the second semiconductor material layer 14 can be compositionally the same as, or compositionally different from, the first semiconductor material that provides the first semiconductor material layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the first semiconductor material layer 10 and the second semiconductor material that provides the second semiconductor material layer 14. In one example, the first semiconductor material layer 10 is composed of silicon, the etch stop layer 12 is composed of silicon dioxide, and the second semiconductor material layer 14 is composed of silicon. In another example, the first semiconductor material layer 10 is composed of silicon, the etch stop layer 12 is composed of silicon germanium, and the second semiconductor material layer 14 is composed of silicon.

The substrate including the first semiconductor material layer 10, the etch stop layer 12 and the second semiconductor material layer 14 can be formed utilizing techniques well known to those skilled in the art. For example, the substrate including the first semiconductor material layer 10, the etch stop layer 12 and the second semiconductor material layer 14 can be formed by a separation by ion implantation of oxygen process, or wafer bonding.

The placeholder material layer 16L is composed of a fourth semiconductor material that is compositionally different from an uppermost semiconductor material portion of the substrate as well as the semiconductor materials that provide the sacrificial semiconductor material layers 18L and the semiconductor channel material layers 20L. In one example, the placeholder material layer 16L is composed of a silicon germanium alloy having a germanium content of from 40 atomic percent to 75 atomic percent. Typically, the placeholder material layer 16L has a thickness from 5 nm to 20 nm; although other thicknesses are contemplated and can be employed as the thickness of the placeholder material layer 16L.

As mentioned above, the material stack includes alternating sacrificial semiconductor material layers 18L and semiconductor channel material layers 20L. In some embodiments and as is illustrated in FIGS. 2A, 2B and 2C, there is an equal number of sacrificial semiconductor material layers 18L and semiconductor channel material layers 20L. That is, the material stack can include ‘n’ number of semiconductor channel material layers 20L and ‘n’ number of sacrificial semiconductor material layers 18L, wherein n is an integer starting from one. By way of one example, the material stack includes three sacrificial semiconductor material layers 18L and three semiconductor channel material layers 20L. Each sacrificial semiconductor material layer 18L is composed of a fifth semiconductor material, while each semiconductor channel material layer 20L is composed of a sixth semiconductor material that is compositionally different from the fifth semiconductor material; note that the fifth and sixth semiconductor materials are both compositionally different from the fourth semiconductor material.

In some embodiments, the sixth semiconductor material that provides each semiconductor channel material layer 20L is capable of providing high channel mobility for n-type field effect transistor (FET) devices. In other embodiments, the sixth semiconductor material that provides each semiconductor channel material layer 20L is capable of providing high channel mobility for p-type FET devices. The fifth semiconductor material that provides each sacrificial semiconductor material layer 18L, and the sixth semiconductor material that provides each semiconductor channel material layer 20L can include one of the semiconductor materials mentioned above. In one example, each sacrificial semiconductor material layer 18L is composed of a silicon germanium alloy having a germanium content from 20 atomic percent to 40 atomic percent (note that each sacrificial semiconductor material layer 18L is compositionally different from the sacrificial placeholder material layer 16L mentioned above), and the sixth semiconductor material that provides each semiconductor channel material layer 20L is composed of silicon. Other combinations of semiconductor materials are possible as long as the fifth semiconductor material that provides each sacrificial semiconductor material layer 18L is compositionally different from the sixth semiconductor material that provides each semiconductor channel material layer 20L, and the semiconductor materials that provide the sacrificial semiconductor material layers 18L and the semiconductor channel material layers 20L are compositionally different from the semiconductor material that provides the sacrificial placeholder material layer 16L.

Each sacrificial semiconductor material layer 18L can have a first thickness, and each semiconductor channel material layer 20L can have a second thickness. In the present application, the first thickness can be equal to, greater than, or less than, the second thickness.

The exemplary structure shown in FIGS. 2A, 2B and 2C can be formed by first depositing the sacrificial placeholder material layer 16L on the substrate (in the illustrated embodiment the sacrificial placeholder material layer 16L is formed on the second semiconductor material layer 14 of the substrate), and thereafter second depositing the material stack on the sacrificial placeholder material layer 16L. The second depositing includes forming alternating blanket layers of the fifth semiconductor material and the sixth semiconductor material mentioned above. The first and second depositing can include one of chemical vapor deposition (CVD), plasma enhanced chemical vapor deposition (PECVD), or epitaxial growth. The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking.

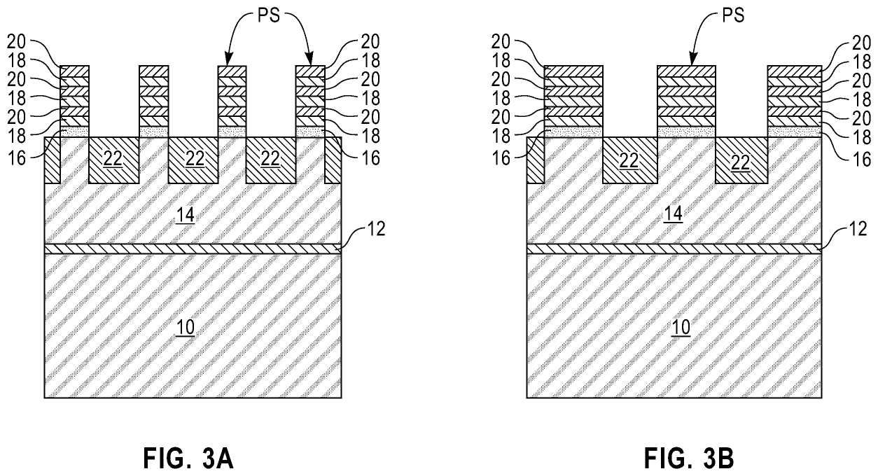

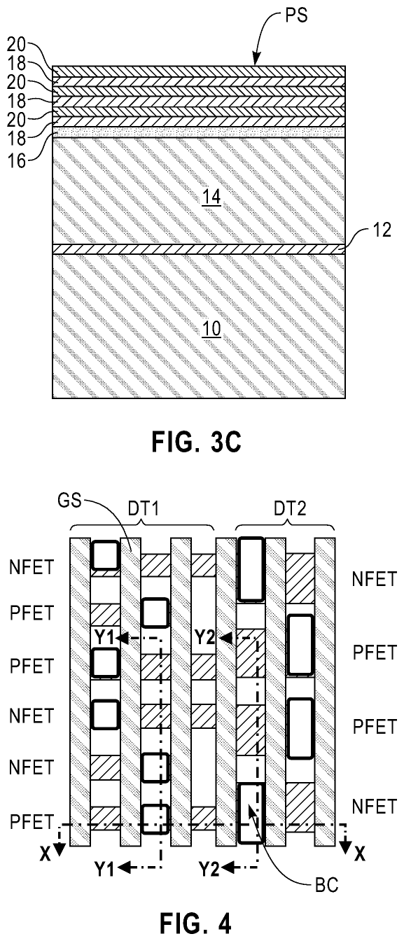

Referring now FIGS. 3A, 3B and 3C, there are illustrated the exemplary semiconductor structure shown in FIGS. 2A, 2B and 2C, respectively, after patterning the material stack and the placeholder material layer 16L into individual patterned material stacks, PS, each individual patterned material stack, PS, includes a remaining portion of the material stack and a remaining portion of the placeholder material layer 16L. That is, each individual patterned material stack, PS, includes a remaining portion of the placeholder material layer 16L (hereinafter patterned placeholder material layer 16), a remaining portion of each sacrificial semiconductor material layer 18L (hereinafter patterned sacrificial semiconductor material layer 18), and a remaining portion of each semiconductor channel material layer (hereinafter patterned semiconductor channel material layer 20). As is illustrated, each patterned material stack, PS, that is formed in FIG. 3A has a first width, while each patterned material stack, PS, that is formed in FIG. 3B has a second width, wherein the second width is greater than the first width.

The patterning of the material stack includes lithography and etching. In some embodiments, a hard mask can be formed on the top of the material stack and that hard mask is patterned by lithography and etching to formed patterned hard masks on the material stack. The patterned hard masks can be designed to have different widths depending on the region that the patterned hard masks are formed. The pattern providing by the patterned hard masks can be transferred into the material stack by etching, and thereafter the patterned hard masks can be removed from each of the individual patterned material stacks, PS.

As is further shown in FIGS. 3A-3B, a shallow trench isolation structure 22 can be formed into the substrate; in the illustrated embodiment the shallow trench isolation structure 22 is formed into the second semiconductor material layer 14. The shallow trench isolation structure 22 is composed of any trench dielectric material such as, for example, silicon oxide. In some embodiments, a trench dielectric liner composed of, for example, SiN, can be present along a sidewall and a bottom wall of the trench dielectric material. The shallow trench isolation structure 22 can have a topmost surface that is coplanar with a topmost surface of the non-etched portion of the substrate; in the illustrated embodiment the shallow trench isolation structure 22 can have a topmost surface that is coplanar with a topmost surface of the non-etched portion of the second semiconductor material layer 14. The shallow trench isolation structure 22 can be formed by first forming (by lithography and etching) a trench in an upper portion of the substrate (in the illustrated embodiment the trench is formed into an upper portion of the second semiconductor material layer 14), depositing the optional trench dielectric liner material and the trench dielectric material in the trench, and thereafter performing an etch back process.

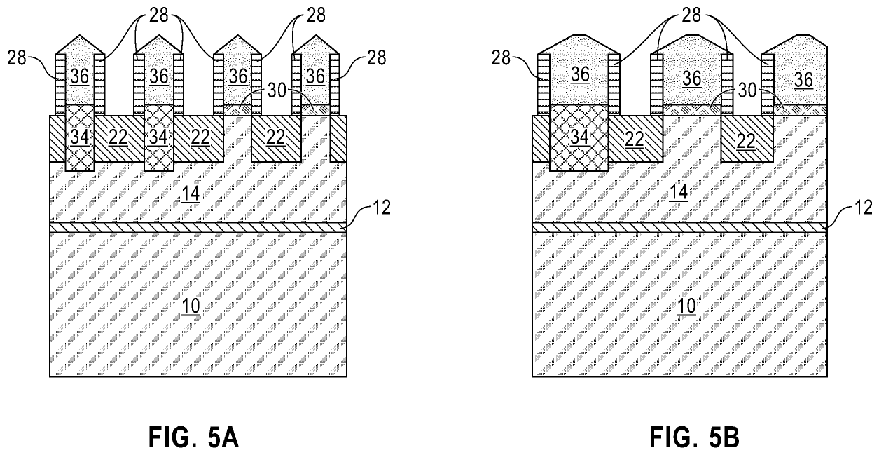

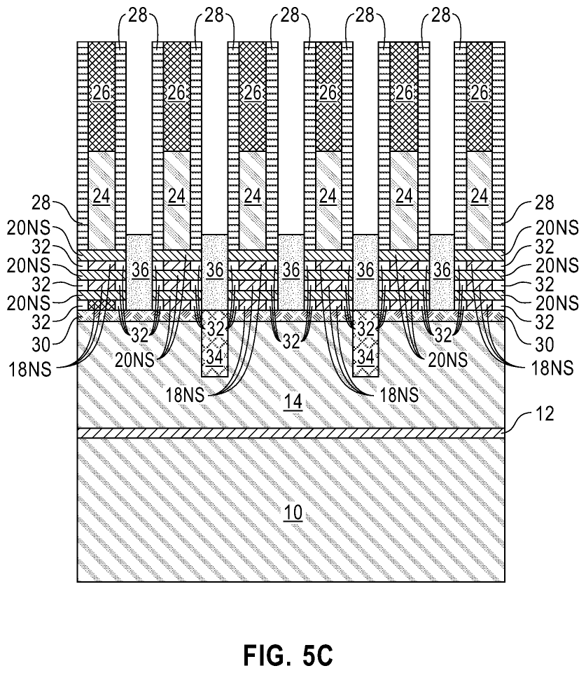

Referring now to FIG. 4, there is shown the device layout of FIG. 1 showing the areas in which backside contacts (BC) will be subsequently formed. The BCs will be formed in areas that will include backside contact placeholder material 34 shown in FIGS. 5A, 5B and 5C below.

Referring now to FIGS. 5A, 5B and 5C, there are illustrated the exemplary semiconductor structure shown in FIGS. 3A, 3B and 3C, respectively, after nanosheet device processing including formation of sacrificial gate structures 24, gate spacers 28, a bottom dielectric isolation layer 30, nanosheet stacks, backside contact placeholder material 34 and source/drain regions 36. Each nanosheet stack includes alternating sacrificial semiconductor material nanosheets 18NS and semiconductor channel material nanosheets 20NS. Also, shown in FIGS. 5A, 5B and 5C are sacrificial gate caps 26 and inner spacers 32 both of which are formed during nanosheet device processing.

The nanosheet device processing includes first forming a sacrificial gate material layer (not specifically shown) and the sacrificial gate cap material layer (not specifically shown). In some embodiments, a sacrificial gate dielectric material layer (also not specifically shown) can be formed prior to forming the sacrificial gate dielectric material. The optional sacrificial gate dielectric material layer can be composed of a dielectric material such as, for example, silicon dioxide. The sacrificial gate material layer includes a sacrificial gate material such as, but not limited to, polysilicon, amorphous silicon, amorphous silicon germanium or amorphous germanium. The sacrificial gate cap is composed of a hard mask material such as, for example, silicon nitride. The optional sacrificial gate dielectric material layer, the sacrificial gate material layer and the sacrificial gate cap material layer can be formed utilizing a deposition process such as, for example, CVD, PECVD, physical vapor deposition (PVD), or atomic layer deposition (ALD). In the present application, the optional sacrificial gate dielectric material layer and the sacrificial gate material layer are deposited prior to depositing the sacrificial gate cap material layer. In some embodiments, the formation of the sacrificial gate cap material layer can be omitted.

The optional sacrificial gate dielectric material layer, the sacrificial gate material layer and the sacrificial gate cap material layer are then patterned by lithography and etching to provide sacrificial gate structures 24 that are capped with sacrificial gate cap 26. Each sacrificial gate structure 24 includes at least a non-etched portion of the sacrificial gate material layer. Each sacrificial gate structure 24 can also include a non-etched portion of the sacrificial gate dielectric material layer. Each sacrificial gate cap 26 includes a non-etched portion of the sacrificial gate cap material layer.

After forming the sacrificial gate structures 24 that are capped with a sacrificial gate cap 26, the patterned placeholder material layer 16 is removed to form a gap beneath each of the patterned material stacks, PS. The patterned material stacks, PS, are non-floating structures which are anchored in place by at least the sacrificial gate structures 24. The removal of patterned placeholder material layer 16 includes an etching process that is selective in removing the fourth semiconductor material that provided the placeholder material layer 16L.

After removing the patterned placeholder material layer 16 from each patterned material stack, nanosheet device processing continues by forming a gate spacer 28 along a sidewall of each sacrificial gate capped-sacrificial gate structure (this structure is a combination of the sacrificial gate structure 24 and the sacrificial gate cap 26). During gate spacer 28 formation, the gap formed beneath each patterned material stack, PS, is filled forming bottom dielectric isolation layer 30. Thus, the gate spacer 28 and the bottom dielectric isolation layer 30 are composed of a same dielectric spacer material, and are of unitary construction. Exemplary dielectric spacer materials that can be used in providing the gate spacer 28 and the bottom dielectric isolation layer 30 include, but are not limited to, silicon dioxide, SiN, SiBCN, SiOCN or SiOC. The gate spacer 28 and the bottom dielectric isolation layer 30 can be formed by a deposition process such as, for example, CVD, PECVD, or ALD.

After forming the gate spacer 28 and the bottom dielectric isolation layer 30, each of the patterned material stack, PS, is converted into a nanosheet stack. This converting includes etching utilizing each gate spacer 28 and sacrificial gate capped-sacrificial gate structure as an etch mask. The etch can include a reactive ion etch. The term “nanosheet stack” denotes that the various material layers that are present in the stack are nanosheets. In the nanosheet stacks, each remaining patterned sacrificial semiconductor material layer 18 can be referred to a sacrificial semiconductor material nanosheet 18NS, and each remaining patterned semiconductor channel material layer 20 can be referred to as a semiconductor channel material nanosheet 20NS.

Next, each sacrificial semiconductor material nanosheet 18NS present in nanosheet stacks are recessed utilizing a recess etching process. The recess etching process is a lateral etching process that is selective for removing a portion of each sacrificial semiconductor material nanosheet 18NS. Note that the recessed sacrificial semiconductor material nanosheets 18NS have a width that is less than a width of each of the semiconductor channel material nanosheets 20NS present in the nanosheet stacks.

Next, inner spacer 32 is formed laterally adjacent to each recessed sacrificial semiconductor material nanosheet 18NS present in each of the nanosheet stacks. Each inner spacer 32 is composed of one of dielectric spacer materials mentioned above for forming the gate spacer 28 and bottom dielectric isolation layer 30. The dielectric spacer material that provides each inner spacer 32 can be compositionally the same as, or compositionally different from, the dielectric material that provides the gate spacer 28 and each bottom dielectric isolation layer 30. The inner spacer 32 is formed by deposition and etching.

After forming the inner spacer 32, backside contact placeholder material 34 is formed in selective locations of the structure by etching through the bottom dielectric isolation layer 30 and an upper portion of the substrate (in the illustrated embodiment this etch is through an upper portion of the second semiconductor material layer 14) that does not include the shallow trench isolation structure 22. The opening created by this etch is then filled (by a deposition process such as, for example, epitaxy, CVD or PECVD) with a sacrificial material such as, for example, SiGe, TiOx, or AlOx, and a recess etch can be performed to provide the backside contact placeholder material 34 shown in FIGS. 5A, 5B and 5C.

Next, source/drain regions 36 are formed. The source/drain regions 36 are typically formed by an epitaxial growth process as defined above. The source/drain regions 36 extend outward from a sidewall of each semiconductor channel material nanosheet 20NS. Some of the source/drain regions 36 are formed in direct physical contact with the bottom dielectric isolation layer 30, while other source/drain regions 36 are formed in direct physical contact with the backside contact placeholder material 34. Each of the source/drain regions 36 is composed of a semiconductor material and a dopant. As used herein, a “source/drain” region can be a source region or a drain region depending on subsequent wiring and application of voltages during operation of the transistor. The semiconductor material that provides each of the source/drain regions 36 is composed of one of the semiconductor materials mentioned above. The semiconductor material that provides the source/drain regions 36 can be compositionally the same, or compositionally different from each semiconductor channel material nanosheet 20NS. The semiconductor material that provides each source/drain region 36 is however compositionally different from each recessed sacrificial semiconductor material nanosheet 18NS. The dopant that is present in the source/drain regions 36 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the source/drain regions can have a dopant concentration of from 4×10²⁰ atoms/cm³ to 3×10²¹ atoms/cm³.

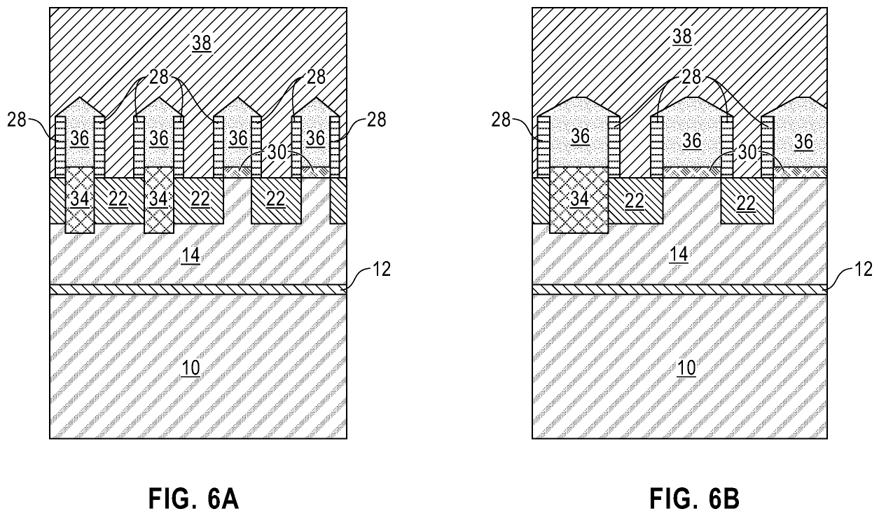

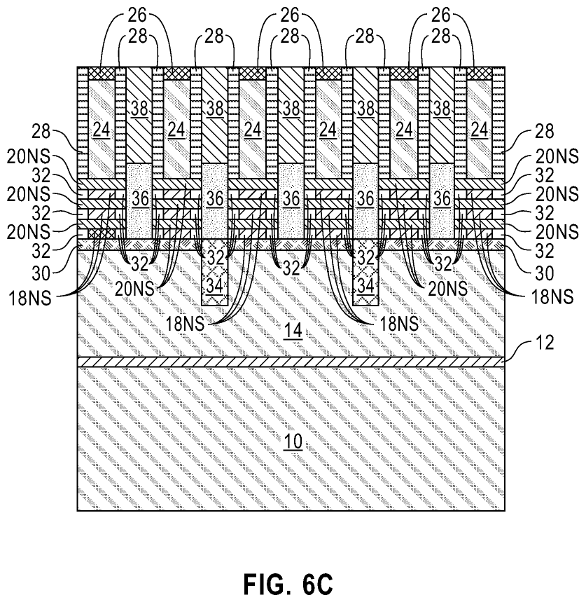

Referring now to FIGS. 6A, 6B and 6C, there are illustrated the exemplary semiconductor structure shown in FIGS. 5A, 5B and 5C, respectively, after forming a frontside interlayer dielectric (ILD) material layer 38 and planarization. The frontside ILD material layer 38 is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted). The frontside ILD material layer 38 can be formed by a deposition process including, but not limited to, CVD, PECVD or spin-on coating. The planarization process includes chemical mechanical polishing (CMP). As is illustrated in FIG. 6C, the planarization process removes an upper portion of each of the sacrificial gate caps 26 and an upper portion of each gate spacer 28.

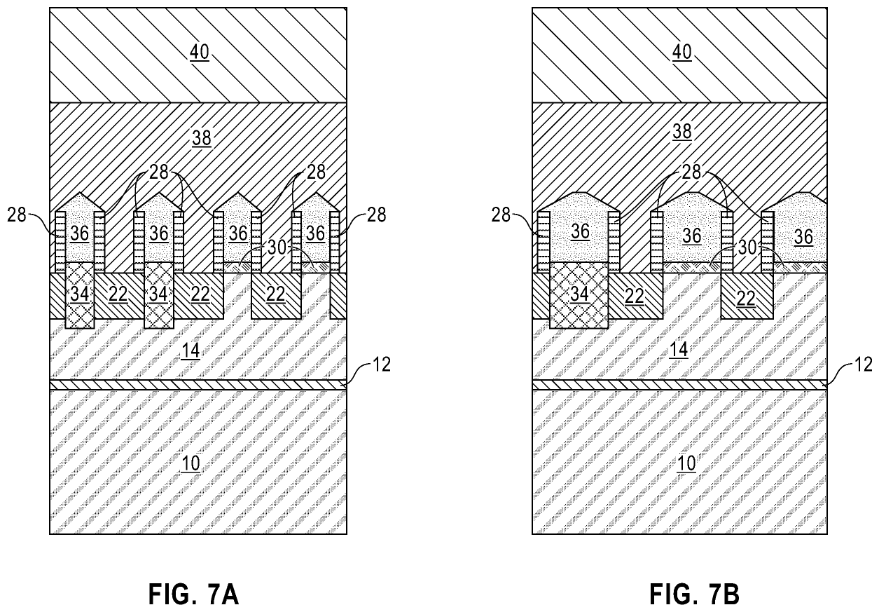

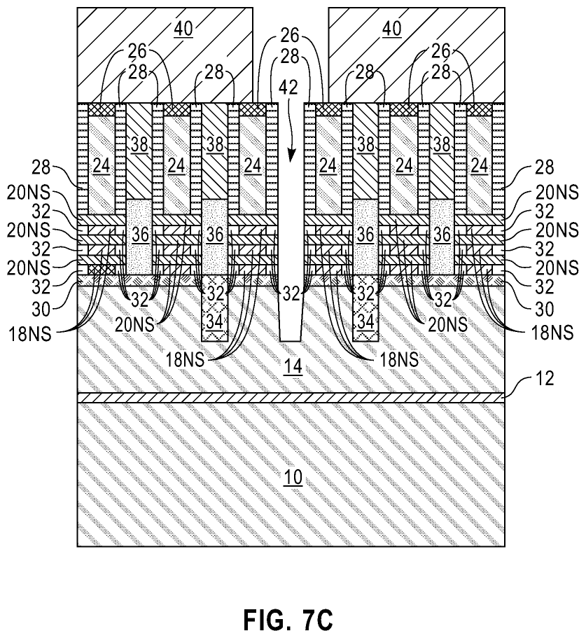

Referring now to FIGS. 7A, 7B and 7C, there are illustrated the exemplary semiconductor structure shown in FIGS. 6A, 6B and 6C, respectively, after forming a self-aligned diffusion break point area 42. The self-aligned diffusion break point area 42 is formed in a region of the structure that is between each of the transistors present in the first device track and each of the transistors present in the second device track. The self-aligned diffusion break point area 42 can be formed by first forming an organic planarizing layer (OPL) 40 on the structure provided in FIGS. 6A, 6B and 6C. The OPL 40 can be formed by a deposition process including, for example, CVD, PECVD or spin-on coating. The OPL 40 is then patterned by lithography and etching to include an opening therein. An etch is then used to transfer the opening in the OPL 40 into an upper portion of the substrate (in the illustrated embodiment, the etch transfer the opening in the OPL 40 into the upper portion of the second semiconductor material layer 14). The etch completely removes any frontside ILD material layer 38, source/drain region 36, and bottom dielectric isolation layer 30 that is located directly beneath the opening in the OPL 40, and the etch partially removes an upper portion of the substrate as shown in FIG. 7C.

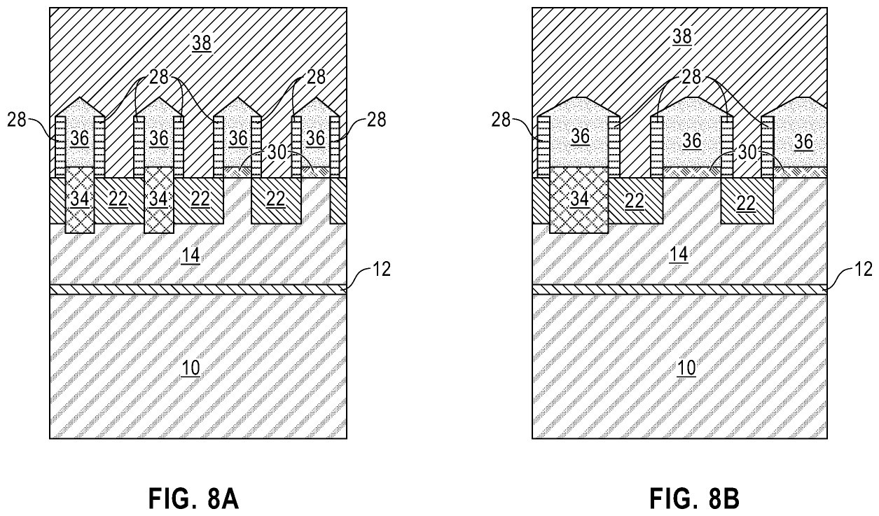

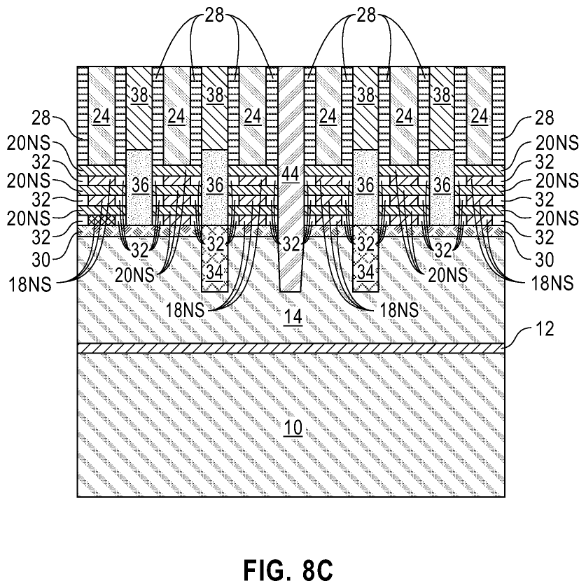

Referring now to FIGS. 8A, 8B and 8C, there are illustrated the exemplary semiconductor structure shown in FIGS. 7A, 7B and 7C, respectively, after forming a dielectric material in the self-aligned diffusion break point area 42 to provide a diffusion break point structure 44. The dielectric material that provides the diffusion break point structure 44 can include, for example, silicon dioxide, silicon nitride, silicon oxynitride; the dielectric material that provides the diffusion break point structure 44 is compositionally different from the dielectric material that provides the sacrificial gate caps 26. Prior to forming this dielectric material, the OPL 40 is removed utilizing a material removal process that is selective in removing OPL 40.

The dielectric material that provides the diffusion break point structure 44 is then deposited (CVD, PECVD, etc.) into the remaining portion of the self-aligned diffusion break point area 42 and on top the structure, and a planarization process such as, CMP, is then employed to provide the final diffusion break point structure 44. This planarization process removes the dielectric material that is formed outside the self-aligned diffusion break point area 42, an upper portion of the frontside ILD material layer 38, the remaining portion of each sacrificial gate cap 26 and an upper portion of the remaining gate spacer 28.

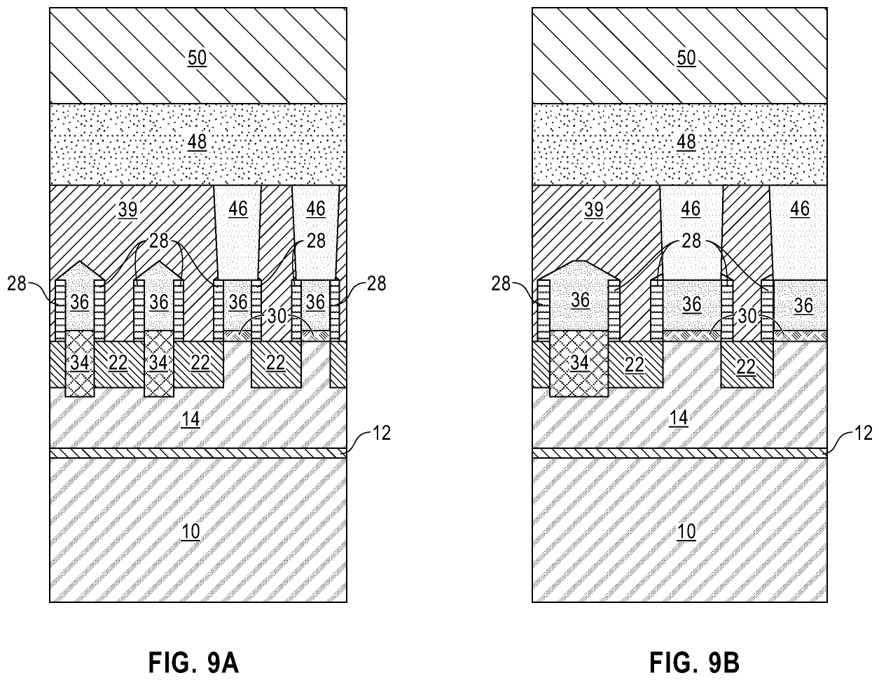

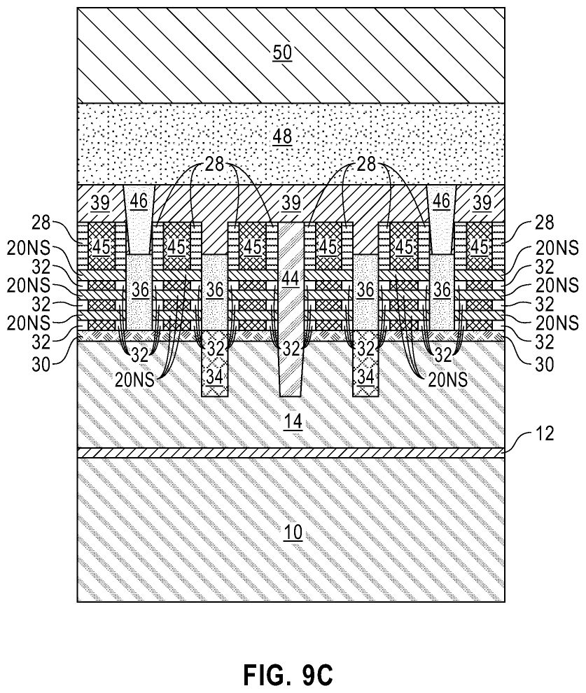

Referring now to FIGS. 9A, 9B and 9C, there are illustrated the exemplary semiconductor structure shown in FIGS. 8A, 8B and 8C, respectively, after further nanosheet device processing including removing the sacrificial gate structures 24, suspending the semiconductor channel material nanosheets 20NS of each nanosheet stack, forming a gate structure 45 wrapping around the suspended semiconductor channel material nanosheets 20NS of each nanosheet stack, forming an additional frontside ILD material, frontside source/drain contact structures 46, a frontside BEOL structure 48 and a carrier wafer 50.

The removal of the sacrificial gate structures 24, which reveals the nanosheet stacks, includes any material removal process such as, for example, etching, that is selective in removing the sacrificial gate structures 24. The removal of the sacrificial semiconductor material nanosheets 18NS, which suspends each semiconductor channel material nanosheet 20NS, includes any material removal process such as, for example, etching, that is selective in removing the sacrificial semiconductor material nanosheets 18NS.

Next, gate structures 45 are formed. The gate structures 45 include a gate dielectric material and a gate electrode, both of which are not separately shown, but intended to be within region defined by the gate structures 45. As is known to those skilled in the art, the gate dielectric material directly contacts a physically exposed surface(s) of each semiconductor channel material nanosheet 20NS, and the gate electrode is formed on the gate dielectric material. The gate dielectric material has a dielectric constant of 4.0 or greater. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg).

The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate structures 45 can be formed by deposition of the gate dielectric material, and gate electrode material, followed by a planarization process.

After forming the gate structures 45, the additional frontside ILD material is formed. The additional frontside ILD material typically includes the same dielectric material as the previously formed frontside ILD material layer 38. Collectively, the additional frontside ILD material and the previously formed frontside ILD material layer 38 provide a frontside middle-of-the-line (MOL) dielectric layer 39 that will house the frontside source/drain contact structures 46. The additional frontside ILD material can be formed utilizing a deposition process used to provide the previous frontside ILD material layer 38.

The frontside source/drain contact structures 46 are then formed utilizing a metallization process that includes forming frontside contact openings in the MOL dielectric material layer 39, and thereafter filling (including deposition and planarization) each frontside contact opening with at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside source/drain contact structures 46 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. Each frontside source/drain contact structures 46 contacts a source/drain region 36 that is located directly on the bottom dielectric isolation layer 30; the frontside source/drain contact structures 46 do not physically contact the source/drain regions 36 that are located on the backside contact placeholder material 34. Each frontside source/drain contact structures 46 has a topmost surface that is coplanar with a topmost surface of the frontside MOL dielectric material layer 39. The frontside source/drain contact structures 46 and frontside MOL dielectric material layer 39 represent a MOL structure.

The frontside BEOL structure 48 can include one or more interconnect dielectric material layers (including one of the dielectric materials mentioned above for the frontside ILD material layer 38) that contain one or more wiring regions (the wiring regions can include any electrically conductive metal or electrically conductive metal alloy) embedded therein. The frontside BEOL structure 48 can be formed utilizing any interconnect device processing technique. In some embodiments, the wiring regions are Cu wiring regions. The carrier wafer 50 can include one of the semiconductor materials mentioned above for the first semiconductor material layer 10. Carrier wafer 50 is bonded to the frontside BEOL structure 48 after frontside BEOL structure 48 formation.

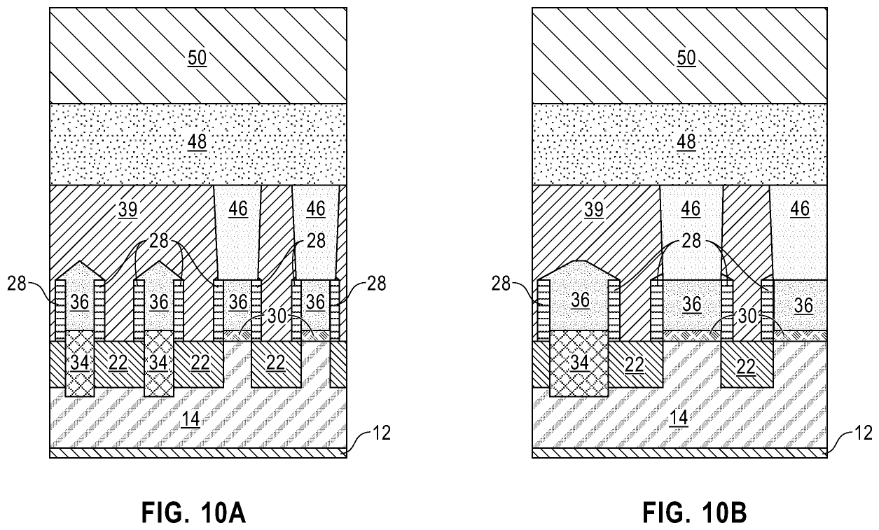

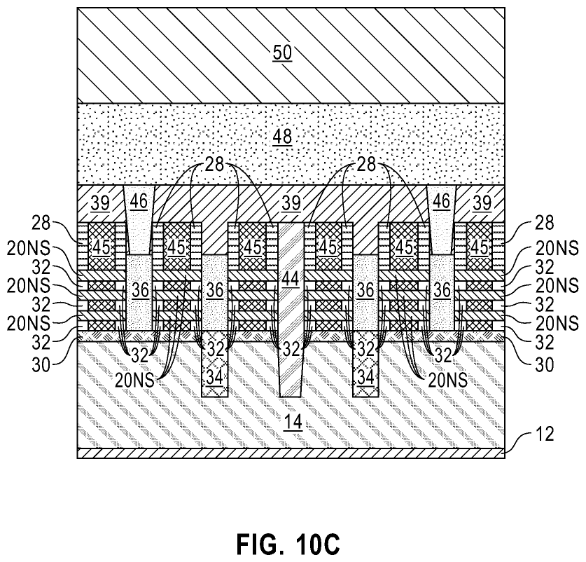

Referring now to FIGS. 10A, 10B and 10C, there are illustrated the exemplary semiconductor structure shown in FIGS. 9A, 9B and 9C, respectively, after removing the first semiconductor material layer 10 of the substrate. The removal of the first semiconductor material layer 10 typically includes flipping the wafer 1800 to physically expose a backside of the substrate. This flipping step is not shown in the drawings of the present application for clarity. In the illustrated embodiment, the substrate includes the first semiconductor material layer 10, the etch stop layer 12, and the second semiconductor material layer 14. Thus, the flipping can physically expose the first semiconductor layer 10 of the substrate. This flipping step will allow backside processing of the exemplary structure. Backside processing occurs on a side of a wafer opposite the side where the transistors, i.e., gate structures 45, have been formed. Flipping of the structure can be performed by hand or by utilizing a mechanical means such as, for example, a robot arm.

The removal of the physically exposed first semiconductor material layer 10 of the substrate physically exposes the etch stop layer 12 of the substrate. The removal of the first semiconductor material layer 10 of the substrate can be performed utilizing a material removal process that is selective in removing the first semiconductor material that provides the first semiconductor material layer 10.

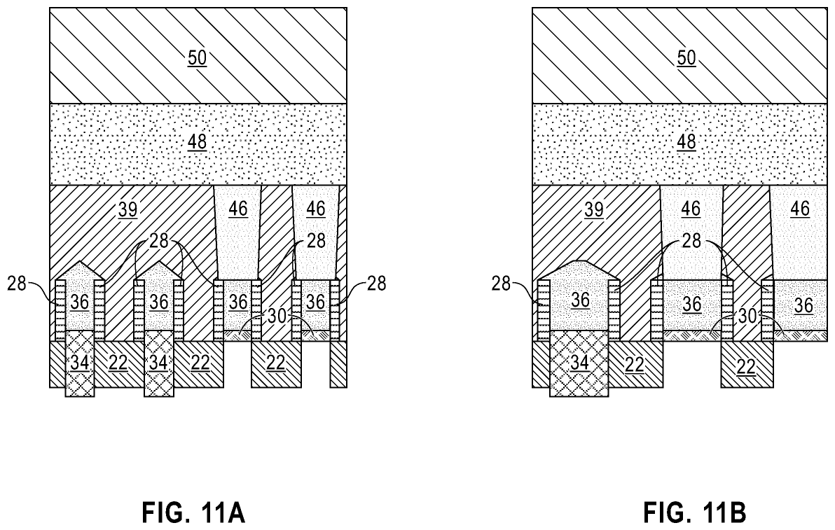

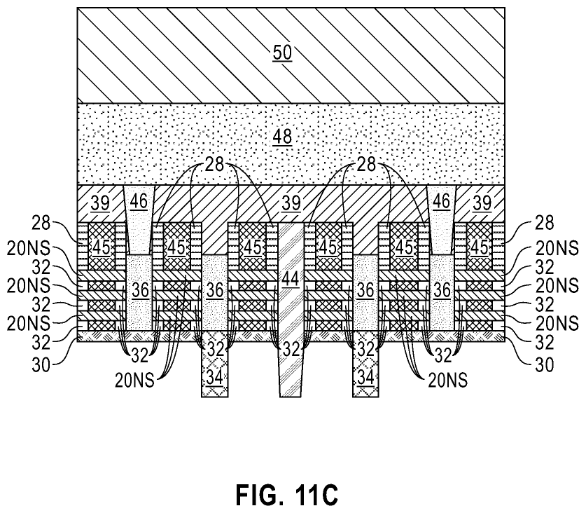

Referring now to FIGS. 11A, 11B and 11C, there is illustrated the exemplary semiconductor structure shown in FIGS. 10A, 10B and 10C, respectively, after removing the etch stop layer 12 and the second semiconductor layer 14 of the substrate. The removal of the etch stop layer 12 includes a material removal process that is selective in removing the etch stop layer 12. The removal of the etch stop layer 12 physically exposes the second semiconductor layer 14 of the substrate. The physically exposed second semiconductor material layer 14 of the substrate can be removed utilizing a material removal process that is selective in removing that layer from the structure. Other material removal processes can be used depending on the type of substrate used. For example, in some embodiments in which substrate is a composed entirely of one semiconductor material, one material removal process can be used instead of the multiple material removal processing steps described herein.

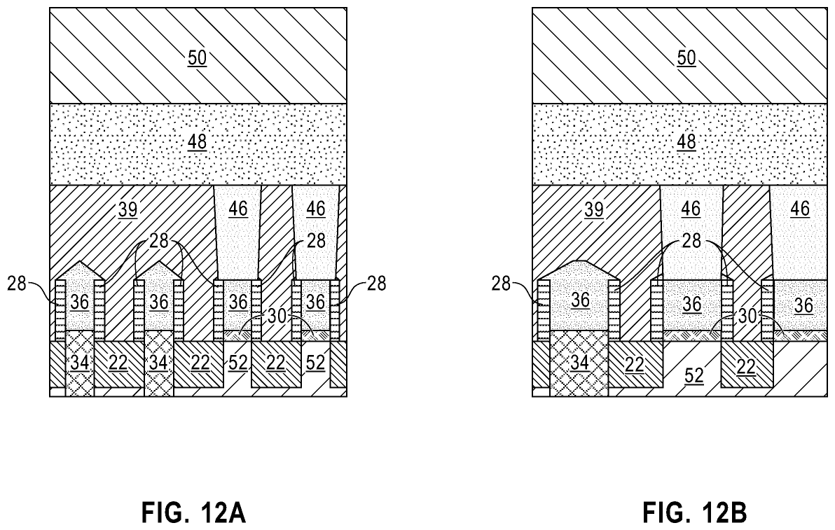

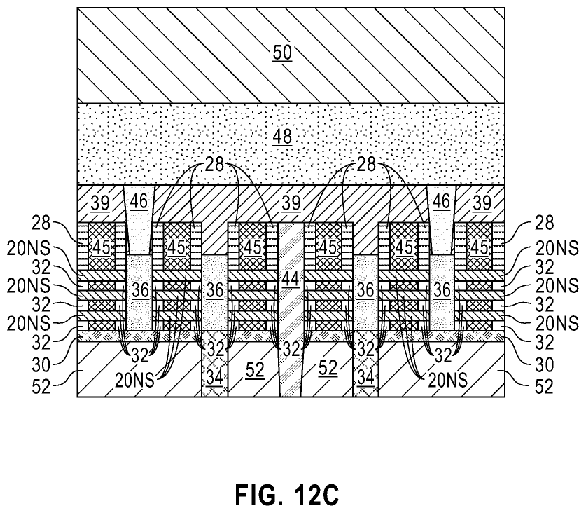

Referring now to FIGS. 12A, 12B and 12C, there are illustrated the exemplary semiconductor structure shown in FIGS. 11A, 11B and 11C, respectively, after forming a first backside ILD material layer 52. The first backside ILD material layer 52 can include one of the dielectric materials mentioned above for the frontside ILD material layer 38. The first backside ILD material layer 52 can be formed utilizing one of the deposition processes mentioned above for forming the frontside ILD material layer 38. A planarization process can follow the deposition process used in forming the first backside ILD material layer 52. In the present application, the first backside ILD material layer 52 has a surface that is coplanar with a surface of the backside contact placeholder material 34. It is noted that the backside contact placeholder material 34 embeds a lower portion of the diffusion break point structure 44.

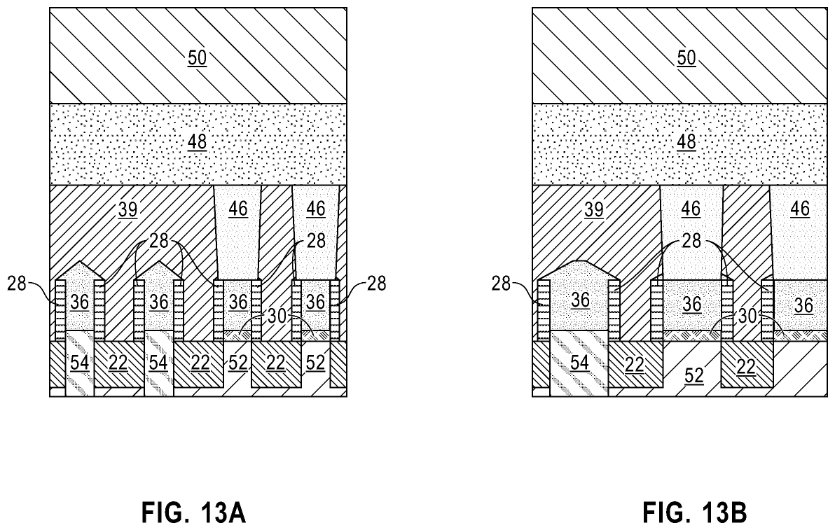

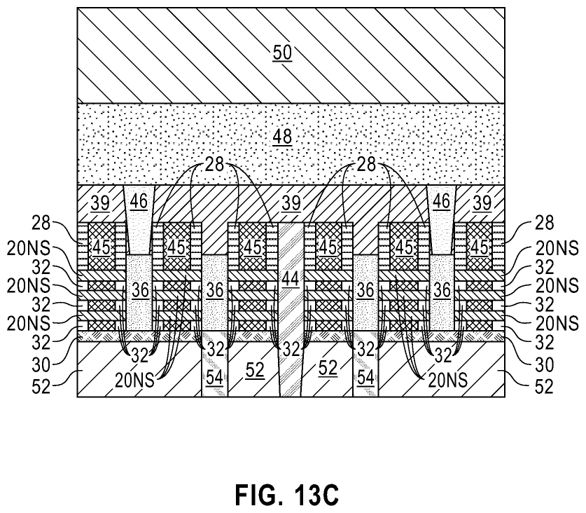

Referring now to FIGS. 13A, 13B and 13C, there are illustrated the exemplary semiconductor structure shown in FIGS. 12A, 12B and 12C, respectively, after removing the backside contact placeholder material 34 to physically expose a surface of some of the source/drain regions 36 and forming backside source/drain contact structures 54 contacting the physically exposed surface of some of the source/drain regions 36. The removal of the backside contact placeholder material 34 includes a material removal process such as etching that is selective in removing the backside contact placeholder material 34. The physically exposed source/drain regions 36 are those source/drain contacts not including a frontside source/drain contact structure 46. The backside source/drain contact structures 54 include materials as mentioned above for the frontside source/drain contact structures 46. The backside source/drain contact structures 54 can be formed by a metallization process as defined above for the frontside source/drain contact structures 46. The backside source/drain contact structures 54 have a surface that is coplanar with a surface of the first backside ILD material layer 52.

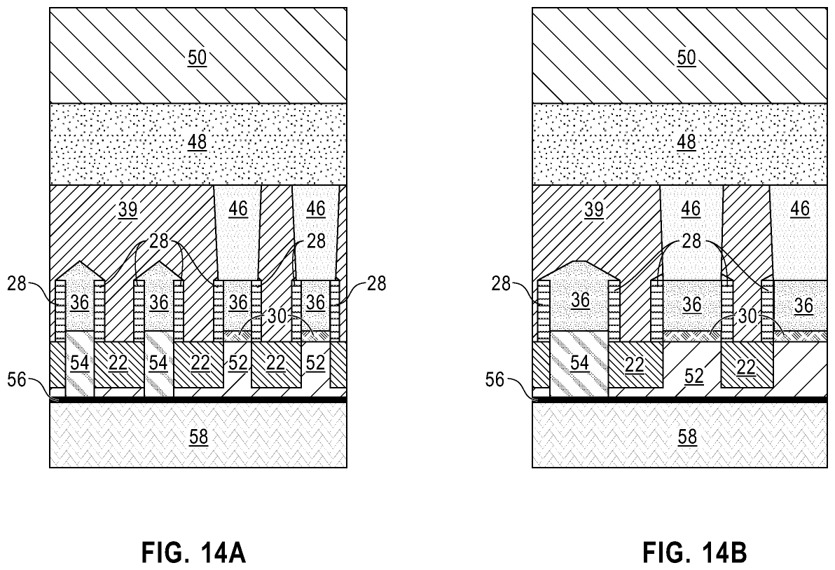

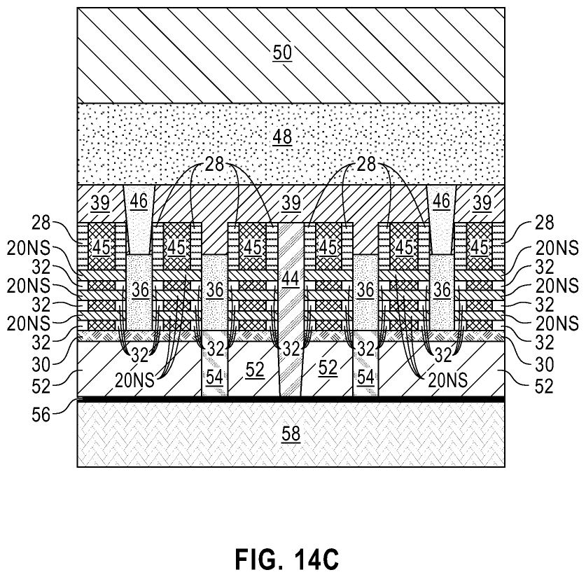

Referring now to FIGS. 14A, 14B and 14C, there are illustrated the exemplary semiconductor structure shown in FIGS. 13A, 13B and 13C, respectively, after forming a diffusion barrier layer 56, and a backside power rail electrically conductive material layer 58.

The diffusion barrier layer 56 includes a diffusion barrier material that will prevent metal ions from the backside power rail electrically conductive material layer 58 to diffuse into the backside source/drain contact structures 54. Illustrative examples of diffusion barrier materials that can be used as the diffusion barrier layer 56 include TiN, TaN or a multilayer structure of TaN and TaN. The diffusion barrier layer 56 can be formed utilizing a deposition process such as, for example, CVD, PECVD, atomic layer deposition (ALD), sputtering or plating. The diffusion barrier layer 56 typically has a thickness from 1 nm to 20 nm; although other thicknesses are contemplated and can be used as the thickness of the diffusion barrier layer 56.

The backside power rail electrically conductive material layer 58 is composed of any electrically conductive power rail material including, but not limited to, tungsten (W), cobalt (Co), ruthenium (Ru), aluminum (Al), copper (Cu), platinum (Pt), rhodium (Rh), or palladium (Pd). The backside power rail electrically conductive material layer 58 can be formed utilizing a deposition process such as, for example, CVD, PECVD, ALD, sputtering or plating. The backside power rail electrically conductive material layer 58 typically has a thickness from 10 nm to 100 nm; although other thicknesses are contemplated and can be used as the thickness of the backside power rail electrically conductive material layer 58.

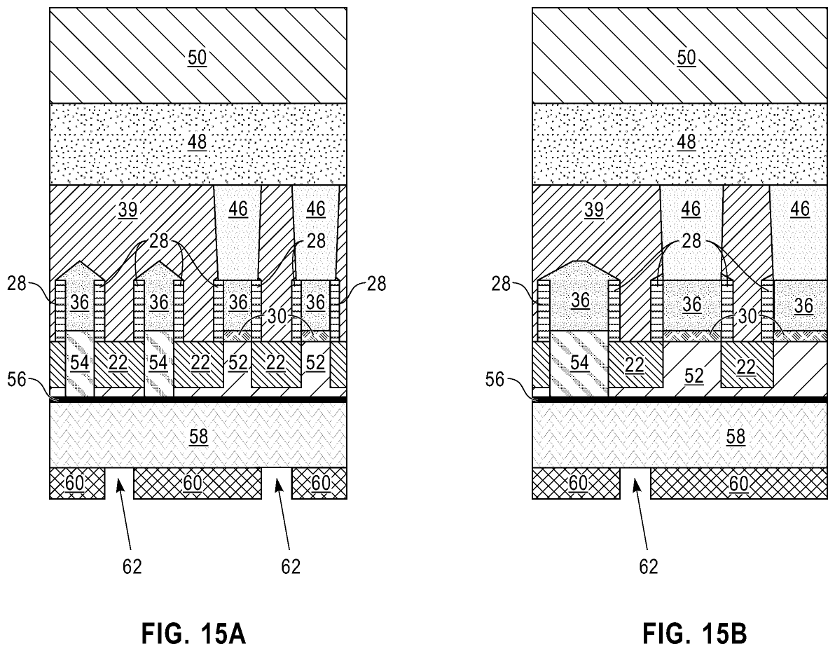

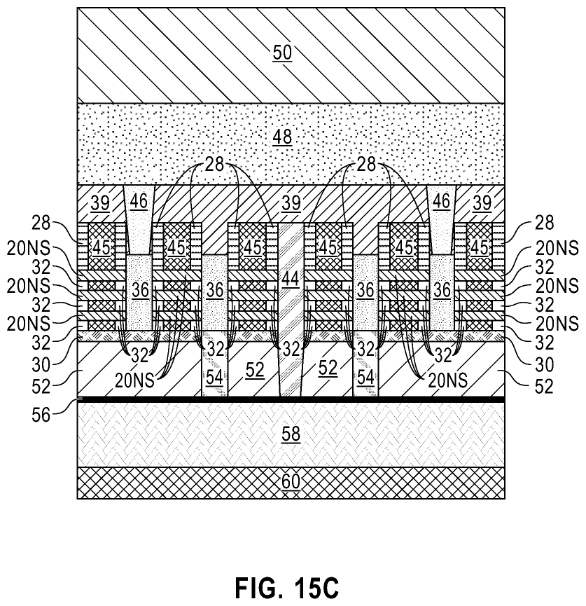

Referring now to FIGS. 15A, 15B and 15C, there are illustrated the exemplary semiconductor structure shown in FIGS. 14A, 14B and 14C, respectively, after forming a hard mask layer 60 on the backside power rail electrically conductive material layer 58, and performing a first backside metal cut (i.e., a X direction cut) into hard mask layer 60. Openings 62 are formed by this metal cut in the X direction. The hard mask layer 60 includes a dielectric material such as, for example, silicon dioxide or silicon nitride. The metal cut in the X direction includes lithography and a metal etch.

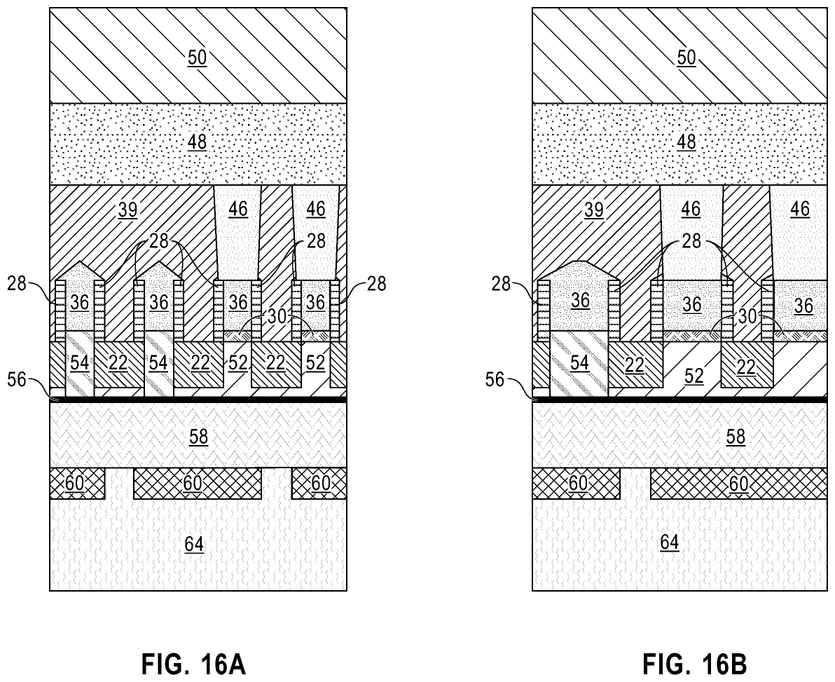

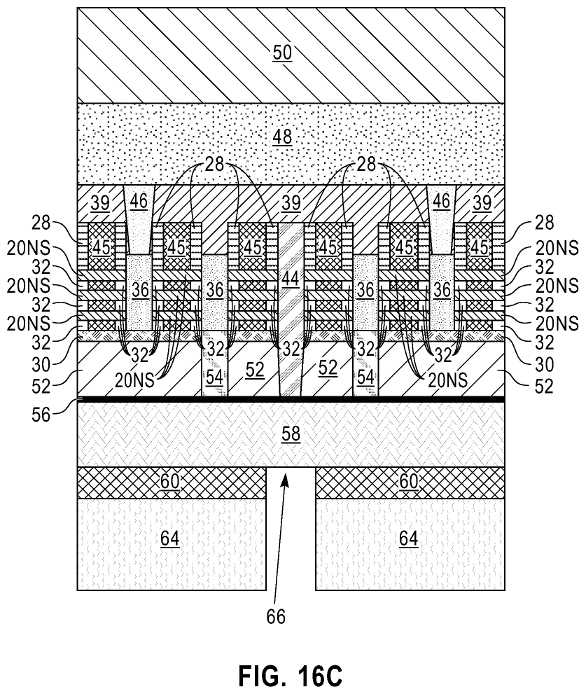

Referring now to FIGS. 16A, 16B and 16C, there are illustrated the exemplary semiconductor structure shown in FIGS. 15A, 15B and 15C, respectively, after forming organic planarization layer 64, and performing a second backside metal cut (i.e., a Y direction cut) into the organic planarization layer 64 and hard mask layer 60. Opening 66 is formed by this metal cut in the Y direction. The organic planarization layer 64 fills in openings 62 and is formed utilizing a deposition process such as, for example, CVD, PECVD or spin-on coating. Opening 66 is located in an area beneath the diffusion break point structure 44. The metal cut in the Y direction includes lithography and a metal etch.

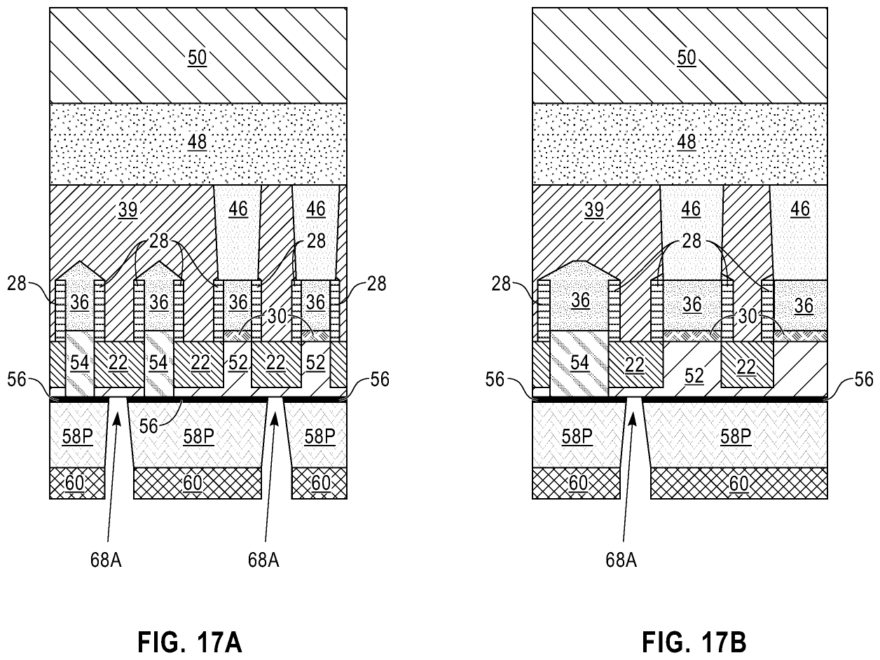

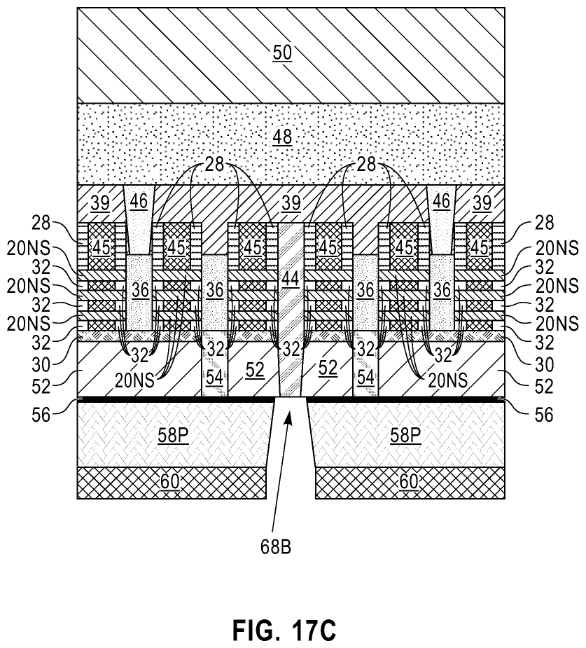

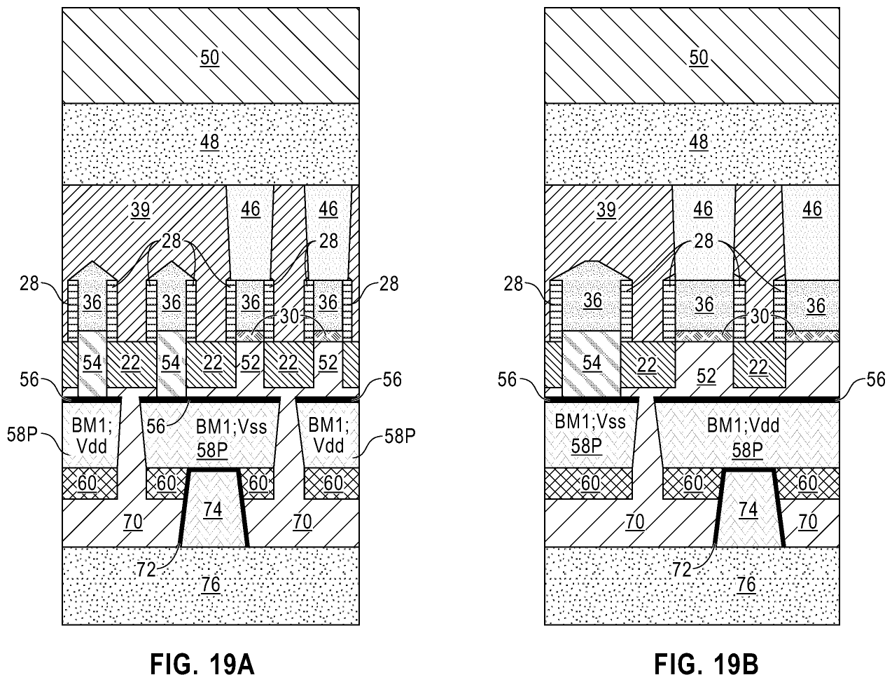

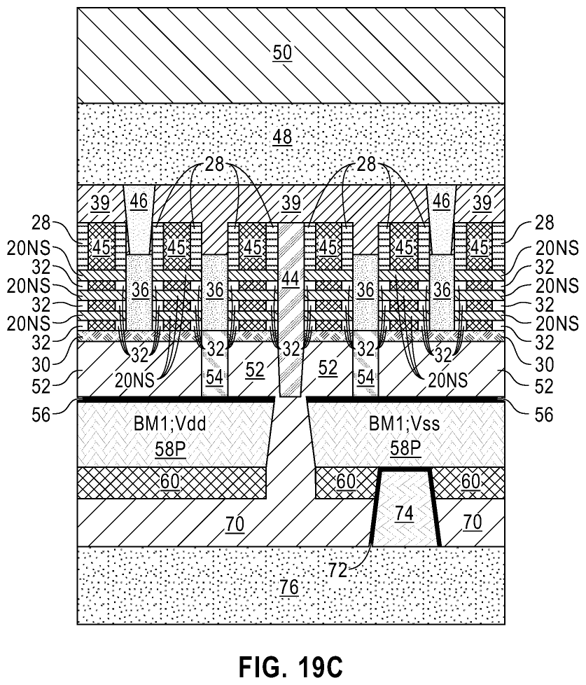

Referring now to FIGS. 17A, 17B and 17C, there are illustrated the exemplary semiconductor structure shown in FIGS. 16A, 16B and 16C, respectively, after removing the organic planarization layer 64, and patterning utilizing the patterned hard mask layer 60 as an etch mask. The backside power rail electrically conductive material layer 58 is patterned by this process into individual backside power islands 58P. The removal of the organic planarization layer 64 is performed utilizing any material removal process that is selective in removing the organic planarization layer 64 from the structure. The patterning includes a metal etch that is selective in etching the backside power rail electrically conductive material layer 58. Openings 68A and 68B are formed. Openings 68A are in the X direction, while opening 68B is in the Y-direction. This patterning step cuts the backside power rail electrically conductive material layer 58 in the X and Y directions. Thus, individual backside power islands 58P are formed at the first backside metal level, BM1, and can be used as Vss or Vdd elements as shown in FIGS. 19A, 19B and 19C. In the present application, a first surface of each of the backside power islands 58P contacts diffusion barrier layer 56, and a second surface of each of the backside power islands 58P opposite the first surface contacts hard mask layer 60, and wherein the first surface of each of the backside power islands 58P is located further from the backside power distribution network 76 than the second surface of each of the backside power islands 58P.

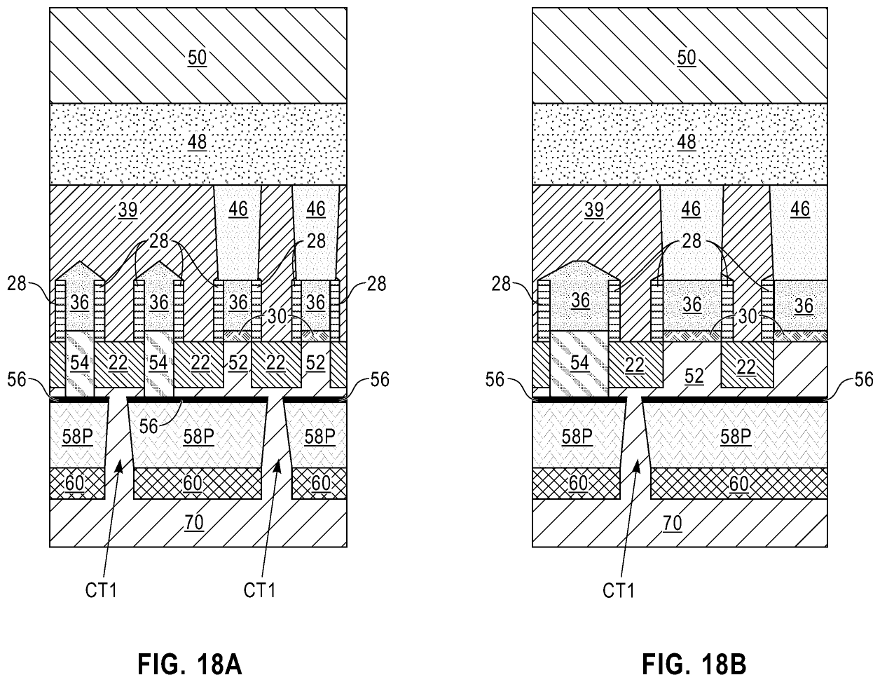

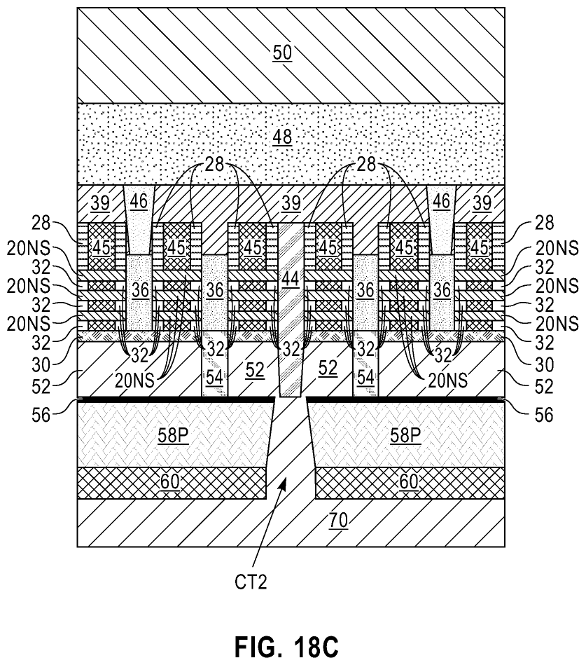

Referring now to FIGS. 18A, 18B and 18C, there are illustrated the exemplary semiconductor structure shown in FIGS. 17A, 17B and 17C, respectively, after forming a second backside ILD material layer 70. Second backside ILD material layer 70 includes one of the dielectric materials mentioned above for the first frontside ILD material layer 38. The dielectric material that provides the second backside ILD material layer 70 can be compositionally the same as, or compositionally different from, the dielectric material that provides the first backside ILD material layer 52. The second backside ILD material layer 70 can be formed by a deposition process such as, for example, CVD, PECVD or spin-coating. As is shown in FIGS. 18A, 18B and 18C, openings 68A and 68B are filled with the second backside ILD material layer 70.

In FIGS. 18A and 18B, a first cut region, CT1, is shown. Each CT1 is present between each n-type field effect transistor to p-type field effect transistor pair present in the first device track and the second device track. In FIG. 18C, there is illustrated a second cut region, CT2. CT2 is present in the area between the first device track and second device track and CT2 and is located beneath the diffusion break point structure 44. It is noted that each CT1 runs perpendicular to CT2, and that both CT1 and CT2 are filled with the second backside interlayer dielectric material layer 70. It is further noted that the second backside interlayer dielectric material layer 70 in CT1 and CT2 directly contact a sidewall of a backside power islands 58P.

Referring now to FIGS. 19A, 19B and 19C, there are illustrated the exemplary semiconductor structure shown in FIGS. 18A, 18B and 18C, respectively, after forming metal via contact structures and a backside power distribution network 76. Each metal via contact structure includes an electrically conductive material 74 and a diffusion barrier liner 72. The diffusion barrier liner 72 can include one of the diffusion barrier materials mentioned above for the diffusion barrier layer 56, and the electrically conductive material 74 includes one of the electrically conductive power rail materials mentioned above for the backside power rail electrically conductive material layer 58. The metal via contact structures (including the electrically conductive material 74 and a diffusion barrier liner 72) can be formed utilizing a metallization process. This metallization process includes forming openings into the second backside ILD material layer 70 and the patterned hard mask layer 60 that physically exposes one of the backside power islands 58P. These openings are the filled to include the electrically conductive material 74 and a diffusion barrier liner 72. Backside power distribution network 76 is formed in contact with the second backside ILD material layer 70 and the each metal via contact structure as shown in FIGS. 19A, 19B and 19C. Thus, the backside power distribution network 76 is in electrical contact with at least one of the backside power islands 58P (now labeled as BM1 Vdd) by the metal via contact structure; some of the backside power islands 589P are configured to be BM1 Vss elements. The backside power distribution network 76 includes elements/components that configured to distribute power to the transistors.

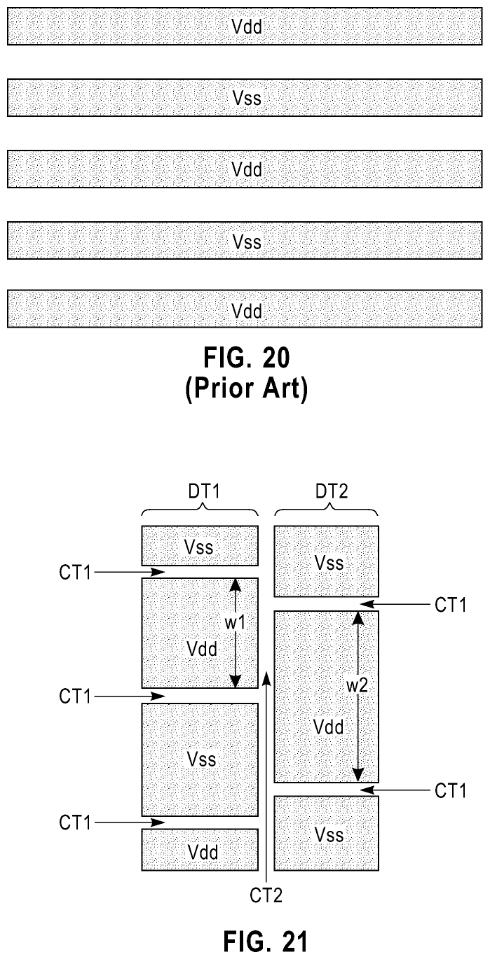

Referring now to FIG. 20, there is illustrated a schematic drawing showing prior art backside power rails, while FIG. 21 illustrated a schematic drawing showing backside power islands in accordance with the present application. As is shown in FIG. 20, the prior art backside power rails (labeled as Vss and Vdd) are metal lines which would continuously extend across different device tracks. In contrast, the FIG. 21 illustrates backside power islands (labeled as Vss and Vdd) located in both DT1 and DT2, wherein the backside power islands that are located in DT1 and the backside power islands that are located in DT2 are isolated by a first cut region, i.e., CT1, and the backside power islands located in the first device track DT1 are separated from the backside power islands located in the second device track DT2 by a second cut region, CT2. As is shown, the CT2 is oriented perpendicular to CT1, and each CT1 is oriented parallel to one another. In the present application, CT1 is located between each n-type field effect transistor to p-type field effect transistor pair present in the first device track and the second device track. In the present application, and as is illustrated in FIG. 21, the backside power islands in DT1 have a first width, w1, and the backside power islands in DT2 have a second width, w2, wherein w1 is less than w2. This aspect provides backside power islands in DT1 that are staggered with respect to the backside power islands in DT2.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

1. A semiconductor structure comprising:
backside power islands located in both a first device track and a second device track, wherein each backside power island located in the first device track and the second device track is isolated by a first cut region, and the backside power islands located in the first device track are separated from the backside power islands located in the second device track by a second cut region, and further wherein the second cut region is oriented perpendicular to the first cut region.

2. The semiconductor structure of claim 1, wherein each of the first device track and the second device track comprises p-type field effect transistors and n-type field effect transistors arranged in rows and columns.

3. The semiconductor structure of claim 2, wherein the first cut region is located between each n-type field effect transistor to p-type field effect transistor pair present in the first device track and the second device track.

4. The semiconductor structure of claim 1, wherein the backside power islands in the first device track have a first width and the backside power islands in the second device track have a second width, wherein the first width is less than the second width.

5. The semiconductor structure of claim 1, wherein the first device track comprises first active areas each of which has a first width and the second device track comprises second active areas each of which has a second width that is greater than the first width.

6. The semiconductor structure of claim 1, wherein the first cut region and the second cut region are both filled with a backside interconnect dielectric material layer.

7. The semiconductor structure of claim 6, wherein the backside interconnect dielectric material layer in both the first cut region and the second cut region is in direct physical contact with a sidewall of at least one of the backside power islands.

8. The semiconductor structure of claim 6, wherein the backside interconnect dielectric material layer contacts a surface of a backside power distribution network.

9. The semiconductor structure of claim 8, wherein the backside power distribution network is connected to at least one of the backside power islands that are located in both the first device track and second device track by a metal via contact structure.

10. The semiconductor structure of claim 9, wherein the metal via contact structure comprises a diffusion barrier liner located along a sidewall and a bottom wall of an electrically conductive metal or electrically conductive metal alloy.

11. The semiconductor structure of claim 8, wherein a first surface of each of the backside power islands contacts a diffusion barrier layer, and a second surface of each of the backside power islands opposite the first surface contacts a hard mask layer, and wherein the first surface of each of the backside power islands is located further from the backside power distribution network than the second surface of each of the backside power islands.

12. The semiconductor structure of claim 1, wherein at least one of the backside power islands is electrically connected to a source/drain region of a p-type field effect transistor or an n-type field effect transistor in at least one of the first device track or the second device track by a backside source/drain contact structure.

13. The semiconductor structure of claim 1, wherein at least one source/drain region of either a p-type field effect transistor or an n-type field effect transistor in at least one of the first device track or the second device track is electrically connected to a frontside back-end-of-the-line (BEOL) structure by a frontside source/drain contact structure.

14. The semiconductor structure of claim 13, further comprising a carrier wafer located on a surface of the frontside BEOL structure.

15. The semiconductor structure of claim 13, wherein the source/drain region that is electrically connected to the frontside BEOL structure is located on a surface of a bottom dielectric isolation layer.

16. The semiconductor structure of claim 2, wherein the p-type field effect transistors and the n-type field effect transistors are nanosheet containing transistors comprising a gate structure wrapped around at least one semiconductor channel material nanosheet.

17. The semiconductor structure of claim 1, further comprising a diffusion brake-break point structure separating the first device track from the second device track, wherein the second cut region is located beneath the diffusion brake-break point structure.

18. The semiconductor structure of claim 17, wherein the diffusion brake-break point structure is composed of a dielectric material, and the diffusion brake break point structure extends into a backside interlayer dielectric material layer.

19. The semiconductor structure of claim 18, wherein the backside interlayer dielectric material layer is located above each of the backside power islands.

20. A semiconductor structure comprising:
a first device track located laterally adjacent to a second device track, wherein each of the first device track and the second device track comprises p-type field effect transistors and n-type field effect transistors arranged in rows and columns;
a diffusion break point structure separating the first device track from the second device track; and
backside power islands located in both the first device track and the second device track, wherein the backside power islands that are located in the first device track and the backside power islands that are located in the second device track are isolated by a first cut region, and the backside power islands located in the first device track are separated from the backside power islands located in the second device track by a second cut region, and further wherein the second cut region is located beneath the diffusion break point structure and is oriented perpendicular to the first cut region.

21. The semiconductor structure of claim 20, wherein the first cut region is located between each n-type field effect transistor to p-type field effect transistor pair present in the first device track and the second device track.

22. The semiconductor structure of claim 20, wherein the backside power islands in the first device track have a first width and the backside power islands in the second device track have a second width, wherein the first width is less than the second width.

23. The semiconductor structure of claim 20, wherein the first device track comprises first active areas each of which has a first width and the second device track comprises second active areas each of which has a second width that is greater than the first width.

24. The semiconductor structure of claim 20, wherein the first cut region and the second cut region are both filled with a backside interconnect dielectric material layer.

25. The semiconductor structure of claim 24, wherein the backside interconnect dielectric material layer in both the first cut region and the second cut region is in direct physical contact with a sidewall of at least one of the backside power islands.
